(19) United States
(12) Patent Application Publication
(10) Pub. No.: US 2012/0153381 A1
(43) Pub. Date: Jun. 21, 2012

(54) SEMICONDUCTOR DEVICE AND METHOD FOR FORMING THE SAME

(75) Inventor: Hae Il SONG, Cheongju (KR)

(73) Assignee: Hynix Semiconductor Inc., Icheon (KR)

(21) Appl. No.: 13/187,157

(22) Filed: Jul. 20, 2011

(30) Foreign Application Priority Data
Dec. 17, 2010 (KR) 10-2010-0130013

(51) Int. Cl. H01L 29/78; H01L 21/28

(52) U.S. Cl. 257/330; 438/589; 257/E29.262; 257/E21.19

(57) ABSTRACT

A semiconductor device and a method for forming the same are disclosed. A method for forming a semiconductor device includes forming a trench by etching a semiconductor substrate, forming a barrier metal layer having a thickness of 100 Å or less over a surface of the trench, forming a nucleation layer over the barrier metal layer, configured to include a β-tungsten (β-W) structure, and forming a bulk layer over the nucleation layer so as to bury the bottom of the trench. As a result, resistivity can be reduced and a stable-phase barrier metal layer can be obtained. In addition, productivity is improved so that gate resistance is prevented from increasing.

### CROSS-REFERENCE TO RELATED APPLICATION

The priority of Korean patent application No. 10-2010-0130013 filed on 17 Dec. 2010, the disclosure of which is hereby incorporated in its entirety by reference, is claimed.

### BACKGROUND OF THE INVENTION

Embodiments of the present invention relate to a semiconductor device and a method for forming the same, and more particularly to a semiconductor device including a buried gate and a method for forming the same.

A dynamic random access memory (DRAM) device includes a plurality of unit cells each having a capacitor and a transistor. The capacitor is used to temporarily store data, and the transistor is used to transfer data between a bit line and the capacitor in response to a control signal (word line). The data transfer occurs by using a semiconductor property where electrical conductivity changes depending on the environment. The transistor has three regions: a gate, a source, and a drain. Electrical charges are moved between the source and the drain according to a control signal input to the gate of the transistor. The movement of the electric charges between the source and the drain is conducted through a channel region. The semiconductor property is used in the channel.

In a typical method for manufacturing a transistor, a gate is formed in a semiconductor substrate, and a source and a drain are formed by doping impurities into both sides of the gate. In this case, a channel region of the transistor exists between the source and the drain under the gate. The transistor having a horizontal channel region occupies a predetermined area of a semiconductor substrate. Therefore, for a given transistor, the number of memory cells may determine the size of the semiconductor device.

If the total area of the semiconductor memory device is reduced, the number of semiconductor memory devices per wafer is increased, thereby improving productivity. Several methods for reducing the total area of the semiconductor memory device have been proposed. One method is to replace a conventional planar gate having a horizontal channel region by a recess gate in which a recess is formed in a substrate and a channel region is formed along a curved surface of the recess by forming a gate in the recess. Furthermore, a buried gate has been studied which can reduce parasitic capacitance of a bit line by burying the entire gate within the recess.

Meanwhile, provided that the buried gate has high resistance, an RC delay unexpectedly occurs so that the semiconductor device cannot be normally operated. As a result, it is necessary for the buried gate to be formed of a low-resistance material such as tungsten (W). In order to prevent the peeling problem of the buried gate, a barrier metal layer such as a titanium nitride (TiN) film has been formed at a lower part of the buried gate. The TiN film is in direct contact with a gate oxide film and serves as agate electrode, so that it should have low resistivity and should not affect gate electrode characteristics in response to a variation in thickness of the TiN film.

Therefore, since TiN has a high work function value, it can be recognized that variation in thickness of a TiN material formed by a Metal Organic Atomic Layer Deposition (MOALD) method has little influence upon gate electrode characteristics as compared to another TiN formed by TiCl₄ gas. For reference, the MOALD-based TiN is formed by the following reaction: Ti[N(CH₃)₂]₄→TiN(C)+HN(CH₃)₂+H₂NCH₃+HN(CH₂)₂+the remaining hydrocarbon.

FIG. 1 shows a capacitance-voltage (C-V) graph as a function of thickness of TiN formed by TiCl₄ gas. FIG. 2 shows a capacitance-voltage (C-V) graph in response to a thickness variation of TiN formed by MOALD. FIGS. 3(a) and 3(b) are a cross-sectional view illustrating how the width a buried gate decreases as integration increases.

Referring to FIG. 1, “A” shows an exemplary implementation in which a TiN layer formed by TiCl₄ gas has a thickness of 40 Å, and “B” shows another implementation in which a TiN layer formed by TiCl₄ gas has a thickness of 120 Å. As can be seen from A and B of FIG. 1, different capacitance values are given at the same gate voltage. However, as shown in the C-V graph of FIG. 2, although the TiN formed by MOALD is formed to have different thicknesses of 40 Å (See A′), 80 Å (See B′) and 120 Å (See C′), it has minimal variation in C-V between different thicknesses.

Due to the above-mentioned characteristics, the MOALD-based TiN is used as a barrier metal layer when forming a buried gate. The MOALD-based TiN is characterized by higher resistivity that is about two times higher than that of the TiCl₄-based TiN.

Therefore, as shown in FIG. 3, as the highly-integrated semiconductor device has been developed in the progression from FIG. 3(a) to FIG. 3(b), the relative amount of a barrier metal layer 18 is also increased, resulting in an increase in gate resistance. In more detail, as shown in FIG. 3(a) and FIG. 3(b), a semiconductor device includes a trench (14 or 24) formed by etching a semiconductor substrate (10 or 20) using a hard mask layer (12 or 22) formed over the semiconductor substrate (10 or 20) as an etch mask; a gate oxide film (16 or 26) formed over the surface of the trench (14 or 24); a barrier metal layer (18 or 28) formed at the bottom of the trench (14 or 24) and formed over the gate oxide film (16 or 26); and a gate metal layer (19 or 29) formed over the barrier metal layer (18 or 28) to bury (or fill) the bottom of the trench (14 or 24). In this case, the barrier metal layer (18 or 28) includes a TiN material.

In this case, the trench 14 has a width of W1, but the trench 24 has a width of W2 smaller than the width of W1 due to the increasing integration degree. Therefore, the relative amount of the barrier metal layer 28 in association with the gate metal layer 29 is higher than the relative amount of another barrier metal layer 18 in association with another gate metal layer 19, so that gate resistance is increased and semiconductor device characteristics are unavoidably deteriorated.

### BRIEF SUMMARY OF THE INVENTION

Various embodiments of the present invention are directed to providing a semiconductor device and a method for forming the same that substantially obviate one or more problems due to limitations and disadvantages of the related art.

An embodiment of the present invention relates to a semiconductor device and a method for forming the same, which can solve the problems of the related art in which relative amount of a TiN material formed by an Metal Organic Atomic Layer Deposition (MOALD) applied to a buried gate is gradually increased as a critical dimension (CD) is gradually reduced with the increasing integration degree of the semiconductor device, so that resistance of a gate electrode is increased and semiconductor device characteristics are deteriorated.

In accordance with an aspect of the present invention, a semiconductor device includes a trench contained in a semiconductor substrate; a barrier metal layer formed over a surface of the trench, and having a thickness of 100 Å or less; a nucleation layer formed over the barrier metal layer and within the trench, and having a β-tungsten (β-W) structure; and a bulk layer formed over the nucleation layer and within the trench.

The barrier metal layer may include a titanium nitride (TiN) layer.

The nucleation layer may include a metastable primitive cubic β-phase structure.

The bulk layer may include tungsten (W).

A laminated structure of the barrier metal layer, the nucleation layer, and the bulk layer formes a buried gate.

The semiconductor device may further include a gate oxide film formed under the barrier metal layer and formed over the surface of the trench.

In accordance with another aspect of the present invention, a method for forming a semiconductor device includes forming a trench by etching a semiconductor substrate; forming a barrier metal layer having a thickness of 100 Å or less over a surface of the trench; forming a nucleation layer over the barrier metal layer and within the trench, the nucleation layer being configured to include a β-tungsten (β-W) structure; and forming a bulk layer over the nucleation layer within the trench.

The method may further include, after forming the trench, forming a gate oxide film over the surface of the trench.

The forming of the barrier metal layer may be performed according to a sequential flow deposition (SFD) scheme.

The forming of the barrier metal layer may be performed at a temperature of 650° C. or higher.

The forming of the barrier metal layer may include forming a titanium nitride (TiN) layer by reacting TiCl₄ gas and NH₃ gas; performing a first purge process; performing a NH₃ treatment process; performing a second purge process; and repeating the forming a titanium nitride, first purge process, NH₃ treatment process, and the second purge process until the TiN layer is formed to a have a specific thickness.

The ratio of TiCl₄ gas to NH₃ gas may be maintained at 1:1.

The TiN layer may be deposited to a thickness of 5 Å or less.

The first purge process may be performed for a time that is equal to or greater than a time for the formation of the TiN layer.

The first purge process may pump out by-products generated in the formation of the TiN layer and non-reacted gas.

The NH₃ treatment process may be performed a time that is equal to or greater than a time for the formation of the TiN layer.

The NH₃ treatment process may increase purity of the TiN layer by reaction with a chlorine (CI).

The forming of the nucleation layer may be performed at a temperature of 290° C. to 310° C.

The forming of the nucleation layer may include injecting and flowing B₂H₆ gas; after injecting and flowing the B₂H₆ gas, performing a third purge process; injecting and flowing WF₆ gas; and performing a fourth purge process; and repeating a injecting and flowing the B₂H₆ gas, the third purge process, the injecting and flowing WF₆ gas, and the fourth purge process until the nucleation layer is formed to a have a specific thickness.

The third purge process may be performed for a predetermined time that is at least two times longer than a time for injecting/flowing the B₂H₆ gas.

The fourth purge process may be performed for a predetermined time that is at least ten times longer than a time required for injecting/flowing the WF₆ gas.

The forming of the nucleation layer may include injecting and flowing B₂H₆ gas; performing a fifth purge process; injecting and flowing WF₆ gas; performing a sixth purge process; injecting and flowing SiH₄ gas; performing a seventh purge process; injecting and flowing WF₆ gas; performing an eighth purge process; and repeating the injecting and flowing B₂H₆ gas, the fifth purge process, the injecting and flowing WF₆ gas, the sixth purge process, the injecting and flowing SiH₄ gas, and the eighth purge process until the nucleation layer has a specific thickness, and performing B₂H₆ treatment.

The performing of the B₂H₆ treatment may include injecting and flowing B₂H₆ gas; performing a ninth purge process several times.

The forming of the bulk layer may include reacting WF₆ gas and H₂ gas.

The forming of the bulk layer may be performed at a temperature of less than 350° C.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 shows a capacitance-voltage (C-V) graph according to a thickness variation of TiN formed by a conventional method using TiCl₄ gas.

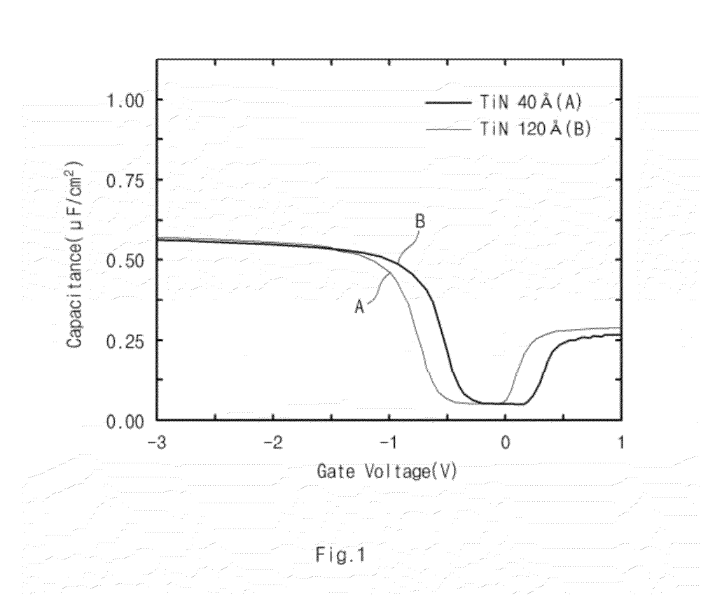

FIG. 2 shows a capacitance-voltage (C-V) graph according to a thickness variation of TiN formed by MOALD.

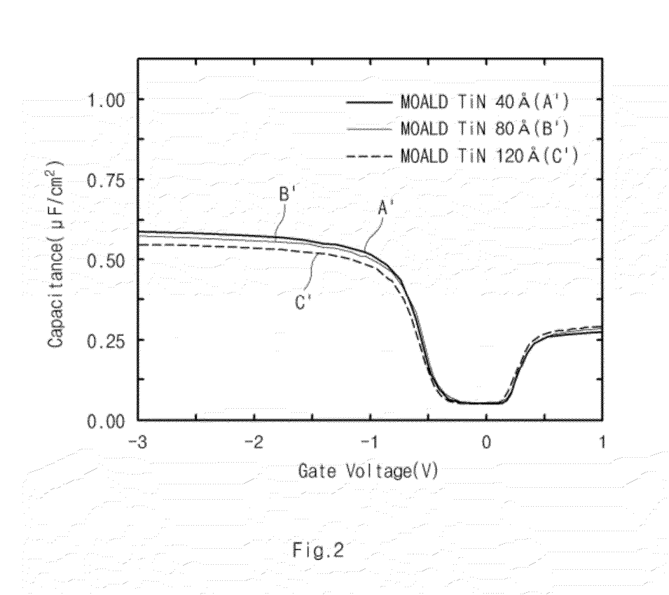

FIGS. 3(a) and 3(b) are a cross-sectional views illustrating a buried gate.

FIG. 4 is a diagram illustrating a process for forming a barrier metal layer according to an embodiment of the present invention.

FIG. 5(i) shows a picture image captured by a transmission electron microscope (TEM) showing an MOALD-based TiN, and FIG. 5(ii) shows a TEM image of TiN according to an embodiment of the present invention.

FIG. 6 shows a capacitance-voltage (C-V) graph according to a thickness variation of a TiN material according to an embodiment of the present invention.

FIG. 7 is a table illustrating the comparison result between characteristics of a laminated structure of an MOALD-based TiN layer and tungsten (W) layer and characteristics of a laminated structure of a TiN layer and tungsten (W) layer according to an embodiment of the present invention.

FIG. 8(i) is a graph illustrating the result of X-ray diffraction (XRD) of an MOALD-based TiN, and FIG. 8(ii) is a graph illustrating the result of X-ray diffraction (XRD) of TiN according to an embodiment of the present invention.

FIG. 9(i) shows a picture image captured by a transmission electron microscope (TEM) of an MOALD-based TiN, and FIG. 9(ii) is a TEM image of TiN according to an embodiment of the present invention.

FIG. 10(i) is a graph illustrating the result of X-ray diffraction (XRD) of a tungsten (W) layer formed over MOALD-based TiN, and FIG. 10(ii) is a graph illustrating the result of X-ray diffraction (XRD) of a tungsten (W) layer formed over TiN according to an embodiment of the present invention.

FIG. 11(i) is a cross-sectional view illustrating an MOALD-based TiN layer and a tungsten (W) layer formed thereon, and FIG. 11(ii) is a cross-sectional view illustrating a TiN layer and a tungsten (W) layer formed thereon according to an embodiment of the present invention.

FIG. 12(i) is a graph illustrating the result of X-ray diffraction (XRD) of a SiH₄-based tungsten nucleation layer, and FIG. 12(ii) is a graph illustrating the result of X-ray diffraction (XRD) of a B₂H₆-based tungsten nucleation layer.

FIG. 13(i) shows a lattice structure of α-tungsten (α-W), and FIG. 13(ii) shows a lattice structure of β-tungsten (β-W).

FIG. 14(i) shows an image captured by a transmission electron microscope (TEM) of a SiH₄-based tungsten nucleation layer, and FIG. 14(ii) shows a TEM image of a B₂H₆-based tungsten nucleation layer.

FIG. 15 is a diagram illustrating a process for forming a tungsten nucleation layer according to an embodiment of the present invention.

FIG. 16(i) is a cross-sectional view illustrating a SiH₄-based tungsten nucleation layer and a tungsten bulk layer formed thereon, and FIG. 16(ii) is a cross-sectional view illustrating a B₂H₆-based tungsten nucleation layer and a tungsten bulk layer formed thereon according to an embodiment of the present invention.

FIG. 17(i) is a TEM image of a tungsten bulk layer formed by reaction of WF₆ and H₂ at a temperature of 350° C. or higher, and FIG. 17(ii) is a TEM image of a tungsten bulk layer formed by a reaction of WF₆ and H₂ at a temperature of less than 350° C.

FIG. 18(i) is a cross-sectional view illustrating an MOALD-based TiN layer and a SiH₄-based tungsten crystal formed thereon, FIG. 18(ii) is a cross-sectional view illustrating a TiN layer and a SiH₄-based tungsten crystal formed thereon according to an embodiment of the present invention, and FIG. 18(iii) is a cross-sectional view illustrating a TiN layer and a B₂H₂-based tungsten crystal formed thereon according to an embodiment of the present invention.

FIG. 19 is a table illustrating a comparison between characteristics of the structures shown in FIG. 18(i), FIG. 18(ii) and FIG. 18(iii).

### DESCRIPTION OF EMBODIMENTS

Reference will now be made in detail to embodiments of the present invention, examples of which are illustrated in the accompanying figures. Wherever possible, the same reference numbers will be used throughout the drawings to refer to the same or like parts.

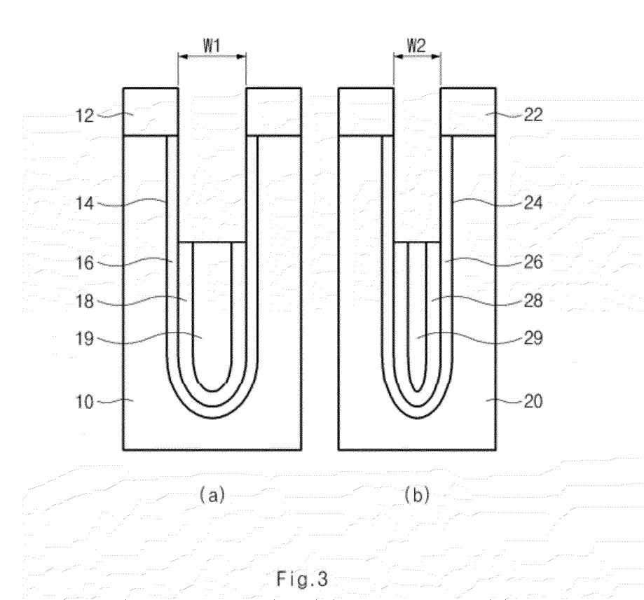

A method for forming a barrier metal layer and a gate metal layer in a buried gate according to an embodiment of the present invention will hereinafter be described with reference to the attached drawings. In this implementation, the buried gate has a structure similar to the structure shown in FIG. 3, and as such a detailed description thereof will herein be omitted for convenience of description.

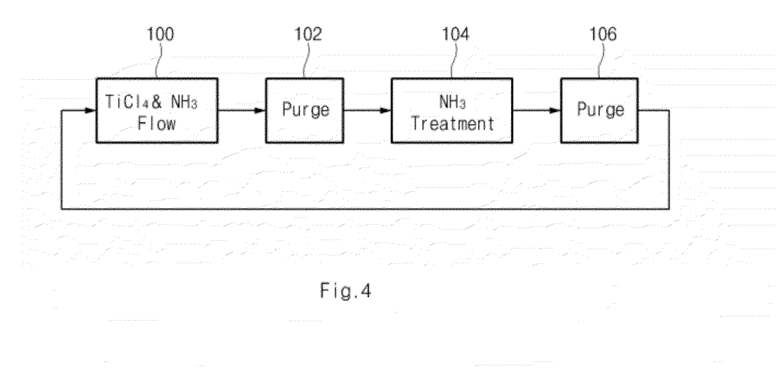

FIG. 4 is a diagram illustrating a process for forming a barrier metal layer according to an embodiment of the present invention. Referring to FIG. 4, the barrier metal layer according to the present embodiment may be formed using a sequential flow deposition (SFD) scheme. In this case, the barrier metal layer may include a TiN material. The SFD scheme may be performed at a temperature of 650° C. or higher, because the level of impurities in the barrier metal layer increases when the process is performed at a temperature of less than 650° C., and the increased impurities may negatively affect the gate oxide film.

In more detail, TiCl₄ gas reacts with NH₃ gas so that a TiN material is formed (See ‘100’ of FIG. 4). In an embodiment, the ratio of the flow of TiCl₄ gas to the flow of NH₃ gas may be set to 1:1. That is, when the flow of TiCl₄ gas is greater than the flow of NH₃ gas, chlorine (Cl) content contained in TiN is increased and the gate oxide film may be deteriorated, so that it is preferable that the ratio of the flow of TiCl₄ gas to the flow of NH₃ gas be set to 1:1. Conversely, when the flow of NH₃ gas is greater than the flow of TiCl₄ gas, TiN step coverage is deteriorated.

Preferably, TiN is deposited to a thickness of 5 Å or less per second. It is difficult to control a process with a higher deposition rate.

Subsequently, a purge process 102 is performed so that by-products reacted in the previous process 100 and non-reacted gasses are removed. Provided that the purge process 102 is performed for a shorter time than the previous process 100, a larger amount of light NH₃ gas is concentrated at a wafer edge as compared to heavier TiCl₄ gas, resulting in an increase in TiN thickness at the wafer edge. When TiN thickness is increased at the wafer edge, step coverage is reduced at the wafer edge. Therefore, the purge process 102 may be performed during the same time as the previous process 100 or for a longer time than the previous process 100. Thereafter, an NH₃ treatment process 104 is performed, where the treatment result reacts with CI so that TiN purity is increased (See ‘104’ of FIG. 4). If the NH₃ treatment 104 has a shorter processing time than the TiN formation process 100, TiN resistivity may be increased due to higher Cl content. Therefore, the NH₃ treatment process 104 may be performed for a predetermined time longer or equal to that of the TiN formation process 100.

After that, a second purge process 106 is performed so that by-products reacted in the previous process 104 are pumped out. Subsequently, the above-mentioned processes 100 to 106 may be repeated several times until a desired TiN thickness is obtained.

By means of the above-mentioned method, a barrier metal layer having a thickness of 100 Å or less may be easily formed. Therefore, the ratio of a barrier metal layer to a gate metal layer can be reduced in response to the increasing integration degree of the semiconductor device.

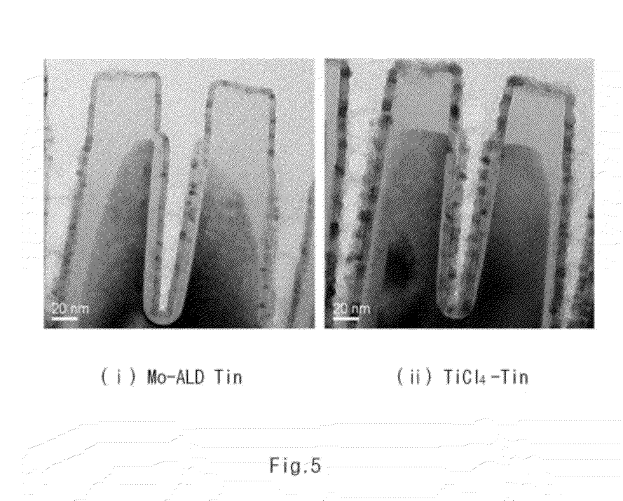

FIG. 5(i) shows an image captured by a transmission electron microscope (TEM) of an MOALD-based TiN, and FIG. 5(ii) is a TEM image of TiN according to an embodiment of the present invention. TiN according to the present invention may have low resistivity, and may be formed of a superior step coverage material even in the deep trench.

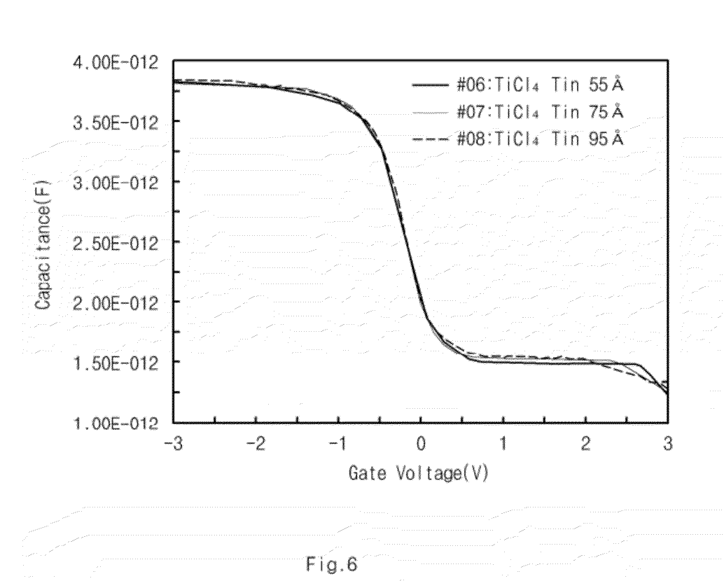

FIG. 6 shows a capacitance-voltage (C-V) graph according to thickness variation of a TiN material according to an embodiment of the present invention. Referring to FIG. 6, in a TiN layer according to an embodiment of the present invention, there is very little difference between C-V characteristics of TiN layers of thicknesses of 55 Å, 75 Å or 95 Å, so that the TiN layer may be used as a barrier metal layer having little influence upon gate characteristics.

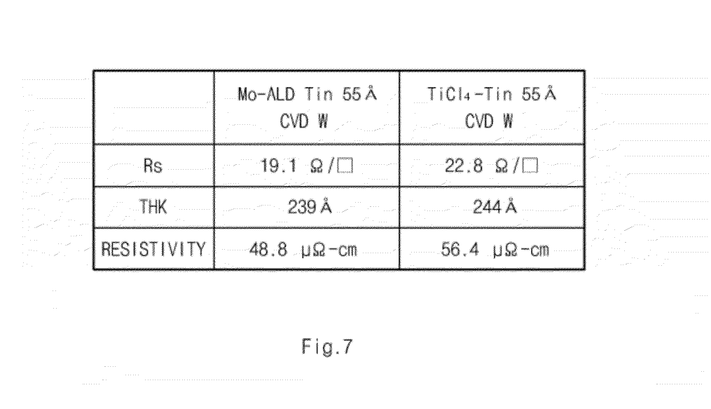

However, although resistivity of the TiN layer formed according to an embodiment of the present invention is reduced, resistivity of a laminated structure where the TiN layer acts as a barrier metal layer in a buried gate and the tungsten (W) layer acts as a gate metal layer in a buried gate is increased as shown in FIG. 7.

FIG. 7 is a table comparing characteristics of a laminated structure of an MOALD-based TiN layer and tungsten (W) layer to characteristics of a laminated structure of a TiN layer and tungsten (W) layer according to an embodiment of the present invention.

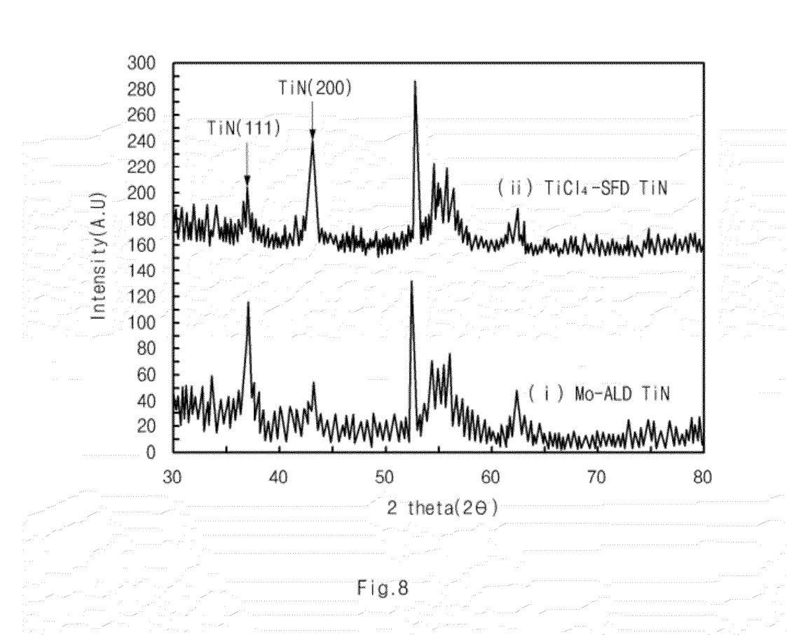

As can be seen from FIG. 7, a laminated structure of TiN and tungsten layers according to an embodiment of the present invention has higher resistance (Rs) and higher resistivity than a laminated structure of the MOALD-based TiN and tungsten layers. Such a phenomenon will hereinafter be described with reference to FIGS. 8 to 11.

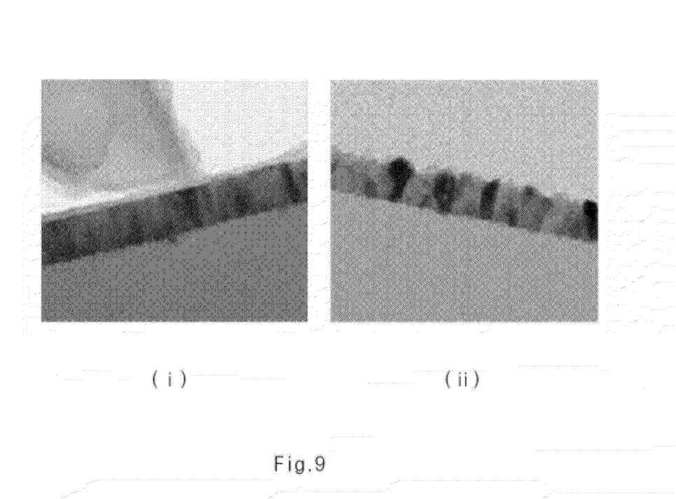

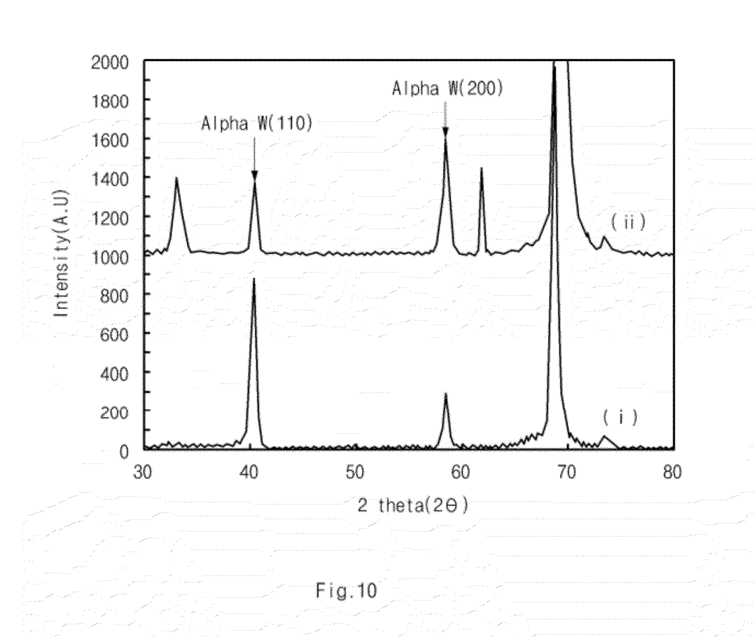

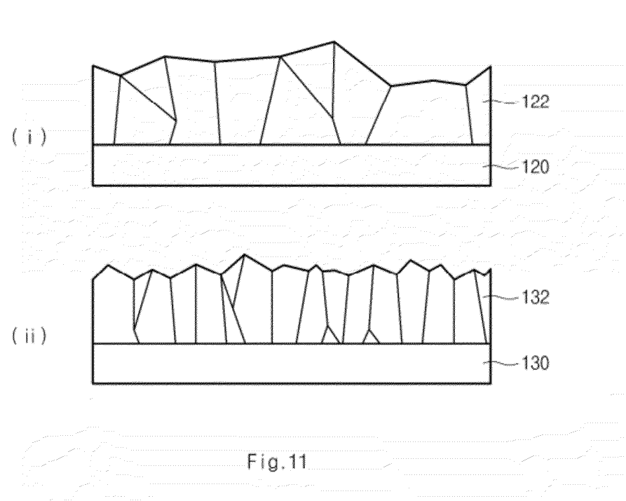

FIG. 8(i) is a graph illustrating the result of X-ray diffraction (XRD) of an MOALD-based TiN, and FIG. 8(ii) shows XRD of TiN according to an embodiment of the present invention. FIG. 9(i) is a TEM image of MOALD-based TiN, and FIG. 9(ii) is a TEM image of TiN according to an embodiment of the present invention. FIG. 10(i) is a graph illustrating the result of X-ray diffraction (XRD) of a tungsten (W) layer formed over an MOALD-based TiN, and FIG. 10(ii) is a graph illustrating the result of X-ray diffraction (XRD) of a tungsten (W) layer formed over TiN according to an embodiment of the present invention. FIG. 11(i) is a cross-sectional view illustrating an MOALD-based TiN layer and a tungsten (W) layer formed thereon, and FIG. 11(ii) is a cross-sectional view illustrating a TiN layer and a tungsten (W) layer formed thereon according to an embodiment of the present invention.

Referring to FIG. 8(i), the MOALD-based TiN does not have a crystallinity peak indicating a crystalline plane in the range of a diffraction angle (2θ) of 30°˜80°, so that it has an amorphous structure as shown in FIG. 9(i), and thus a tungsten (W) layer formed over the MOALD-based TiN layer does not have a substantial peak indicating a crystalline plane as shown in FIG. 10(i). Therefore, as shown in FIG. 11(i), grains are not grown on the basis of a specific plane and are irregularly formed. As a result, resistivity is not increased.

Referring to FIG. 8(ii), a TiN layer according to an embodiment of the present invention has a peak indicating crystallographic planes (200) in the range of a diffraction angle (2θ) of 30° to 80°, so that a TiN layer according to an embodiment of the present invention includes crystalline grains grown on the basis of the crystallographic plane (200) as shown in FIG. 9(ii). Therefore, a tungsten (W) layer formed over TiN layer of FIG. 9(ii) has an α-tungsten (α-W) structure as shown in FIG. 10(ii), and a peak indicating each crystallographic plane (200). Accordingly, as shown in FIG. 11(ii), a tungsten (W) layer formed over the inventive TiN layer formed by the present invention is grown with small-sized grains, so that a grain boundary is increased and electron scattering occurs, resulting in increased resistivity.

Although the TiN layer (120 or 130) is formed parallel to the tungsten layer (122 or 132) as shown in FIG. 11, it is more preferable that the TiN layer (120 or 130) and the tungsten layer (122 or 132) be formed over the trench contained in the semiconductor as shown in FIG. 3.

For reference, assuming that the crystallographic plane (200) has a peak at a specific diffraction angle 200, this means that Bragg's law is satisfied at the crystallographic plane (200), and the peak at ‘(200)’ indicates miller indices. Bragg's law is a law indicating a condition shown by X-rays diffracted from crystal atoms when X-ray wavelength and the distance between crystal atoms are already known, and the Miller index is an index indicating a predetermined ratio at which a crystallographic plane severs a crystal axis. For example, in the case of a crystallographic plane with a Miller index of (001), the X-axis is set to 0, Y-axis is set to 0 and Z-axis is set to 1 in the crystallographic plane 001.

In addition, assuming that a peak value is shown in the remaining parts other than the TiN layer of FIG. 8 and the tungsten (W) layer of FIG. 10, the peak value may be considered to be a peak value of a silicon substrate (semiconductor substrate), and the remaining peak values other than those of the TiN and W layers may be discarded.

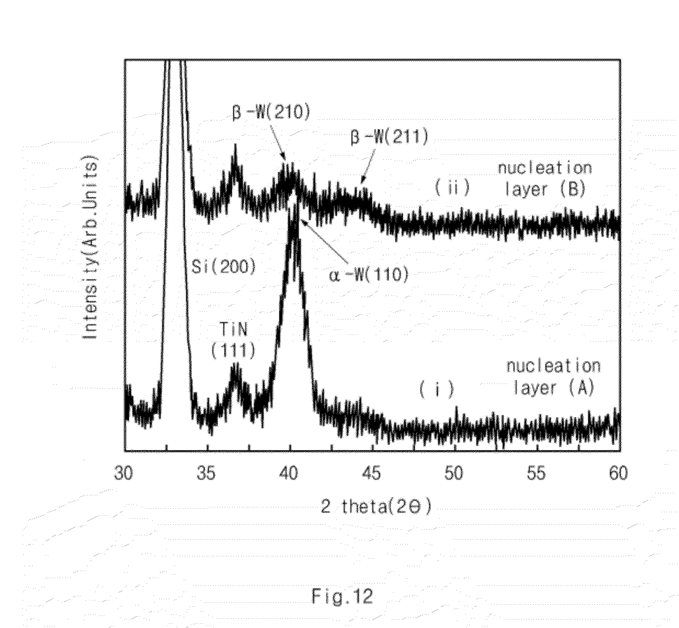

As described above, if tungsten is directly grown on the TiN layer, resistivity is increased, so that the increased resistivity may not affect the TiN crystal using the tungsten nucleation scheme. The tungsten nucleation scheme according to the present invention may allow B₂H₆ to react with WF₆, and as such a detailed description thereof will be given with reference to FIGS. 12 to 14.

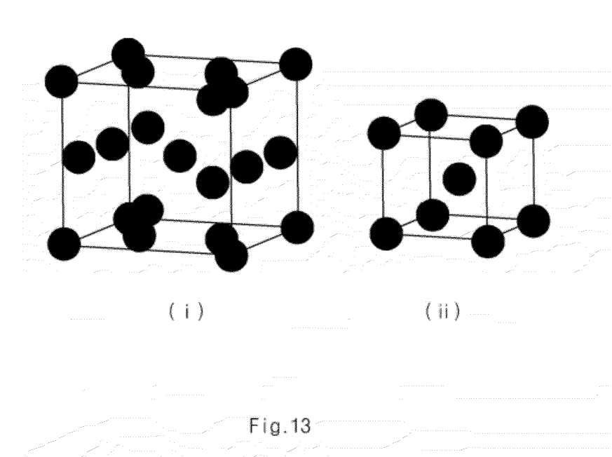

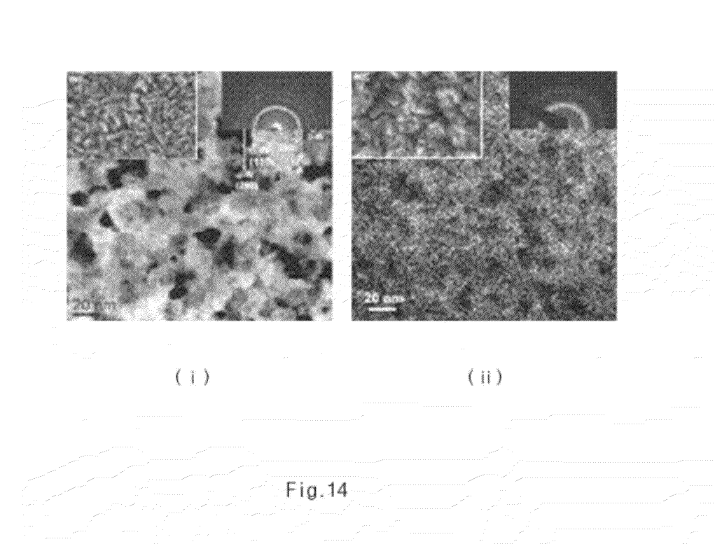

FIG. 12(i) is a graph illustrating the result of X-ray diffraction (XRD) of SiH₄-based tungsten nucleation layer, and FIG. 12(ii) is a graph illustrating the result of X-ray diffraction (XRD) of a B₂H₆-based tungsten nucleation layer. FIG. 13(i) shows a lattice structure of α-tungsten (α-W), and FIG. 13(ii) shows a lattice structure of β-tungsten (β-W). FIG. 14(i) shows an image captured by a transmission electron microscope (TEM) showing a SiH₄-based tungsten nucleation layer, and FIG. 13(ii) shows an image captured by a transmission electron microscope (TEM) showing a B₂H₆-based tungsten nucleation layer.

Referring to FIG. 12(i), the SiH₄-based tungsten nucleation layer is configured in an α-tungsten (α-W) structure, and has a peak on the crystallographic plane (110). As shown in FIG. 13(i), α-tungsten (α-W) is configured in an Equilibrium Body Center Cubic (BCC) structure, so that it has a crystalline structure as shown in FIG. 14(i).

However, referring to FIG. 12(ii), the B₂H₆-based tungsten nucleation layer has a β-tungsten (β-W) structure, and does not have a peak value at a specific plane as shown in FIG. 12(i). That is, the β-tungsten (β-W) structure does not have a peak point at a specific plane so that it is not grown on the basis of a specific plane as in the α-tungsten (α-W) structure. The β-tungsten (β-W) structure has a metastable primitive cubic β-phase structure as shown in FIG. 13(ii), so that it has no grains as shown in FIG. 14(ii). As a result, the β-tungsten (β-W) structure is used as a diffusion barrier for preventing diffusion to the semiconductor substrate.

For reference, in the case of tungsten formed over a MOALD-based TiN layer, grains are grown on the basis of the crystallographic plane (111). Therefore, there is a limitation in increasing the size of grain, so that the tungsten layer formed over the MOALD-based TiN layer has higher resistivity than a tungsten layer grown using the tungsten nucleation scheme for the reaction between B₂H₆ and WF₆.

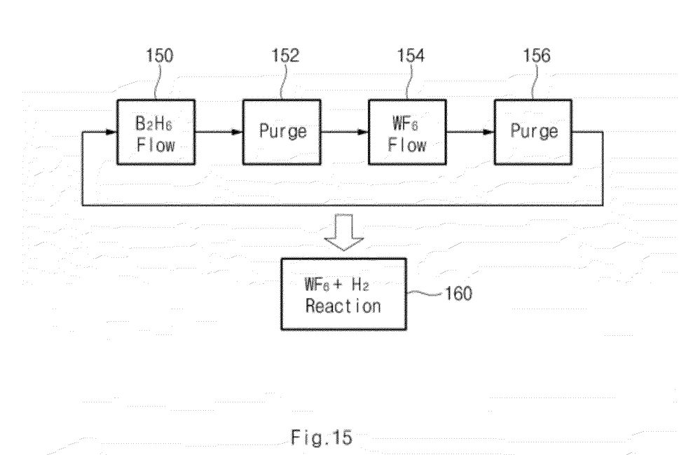

FIG. 15 is a conceptual diagram illustrating a process for forming a tungsten nucleation layer according to an embodiment of the present invention. A method for forming a tungsten nucleation layer by the reaction of B₂H₆ and WF₆ according to a first embodiment of the present invention is as follows. Referring to FIG. 15, B₂H₆ gas is introduced (See ‘B₂H₆ flow’ 150). Subsequently, the purge process 152 is performed. In this embodiment, a processing time of the purge process 152 may be at least two times longer than that of B₂H₆ gas flow. Thereafter, WF₆ gas is introduced (See ‘WF₆ flow’ 154). Subsequently, the purge process 156 is carried out. In this embodiment, the purge process 154 is ten times longer than that of WF₆ gas flow. After that, the above-mentioned process may be repeated until a desired tungsten nucleation layer is formed. For example, the above-mentioned process may be repeated for 5 cycles. As described above, the process for forming the tungsten nucleation player by the reaction between B₂H₆ and WF₆ may be performed at a temperature of 290° C. to 310° C., such that the tungsten nucleation layer has the same structure as in an atomic layer deposition (ALD)-based layer. Thereafter, after the tungsten nucleation layer is formed, WF₆ gas reacts with H₂ gas so that a tungsten bulk layer is formed (See ‘160’ of FIG. 15).

The method for forming a tungsten nucleation layer according to a second embodiment of the present invention may include introducing a flow of B₂H₆, purging the resultant B₂H₆ gas, introducing a flow of WF₆, and purging the resultant WF₆ gas. The method for forming the tungsten nucleation layer may be performed for one cycle (1 cycle). Subsequently, a flow of SiH₄ is introduced, the resultant SiH₄ gas is purged, a flow of WF₆ gas is introduced, and the purge process 156 purges the resultant WF₆ gas. Preferably, the above-mentioned method for forming the tungsten nucleation layer according to the second embodiment of the present invention may be repeated for 5 cycles. Therefore, B₂H₆ treatment may be performed. For the B₂H₆ treatment, the step for injecting/flowing/purging B₂H₆ gas may be repeated for 6 cycles. Thereafter, after the tungsten nucleation layer is formed, WF₆ gas reacts with H₂ gas so that the tungsten bulk layer may be formed.

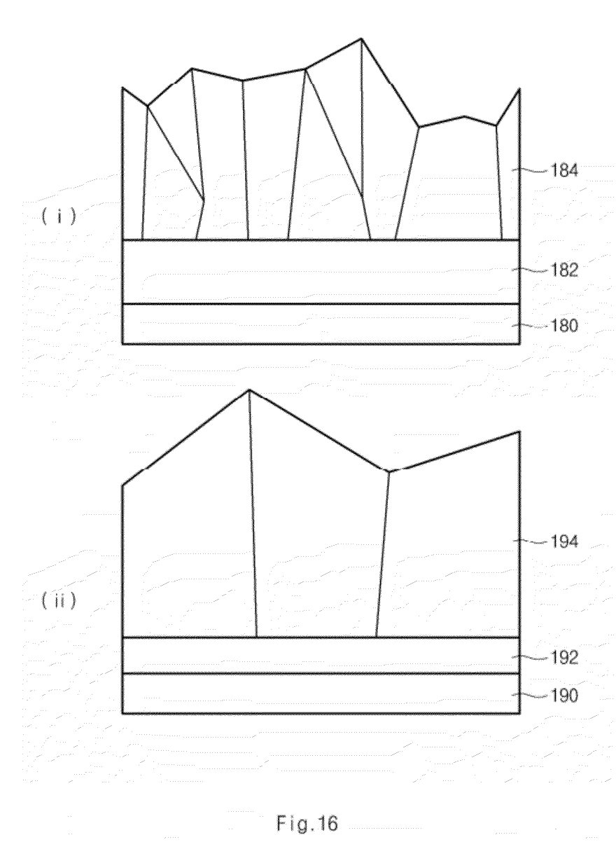

FIG. 16(i) is a cross-sectional view illustrating a SiH₄-based tungsten nucleation layer and a tungsten bulk layer formed thereon, and FIG. 16(ii) is a cross-sectional view illustrating a B₂H₆-based tungsten nucleation layer and a tungsten bulk layer formed thereon according to an embodiment of the present invention.

Referring to FIG. 16, the B₂H₆-based tungsten nucleation layer 192 formed over the TiN layer 190 according to an embodiment of the present invention has lower resistivity than the SiH₄-based nucleation layer 182 formed over the TiN layer 180, so that the B₂H₆-based tungsten nucleation layer 192 is thinner than the SiH₄-based nucleation layer 182. The resultant B₂H₆-based tungsten nucleation layer can reduce the thickness of the tungsten nucleation layer having relatively high resistivity in comparison to the tungsten bulk layer, so that gate resistance can be effectively reduced. The B₂H₆-based tungsten nucleation layer 192 has a low content of impurities and an amorphous structure, so that it can prevent such impurities from being permeated into a lower TiN layer during the growing process of the tungsten bulk layer. In addition, tungsten bulk layer 194 is formed over the amorphous B₂H₆-based tungsten nucleation layer 192, so that tungsten bulk layer 194 has a larger grain than in the other tungsten bulk layer 184 formed over the SiH₄-based tungsten nucleation layer 182.

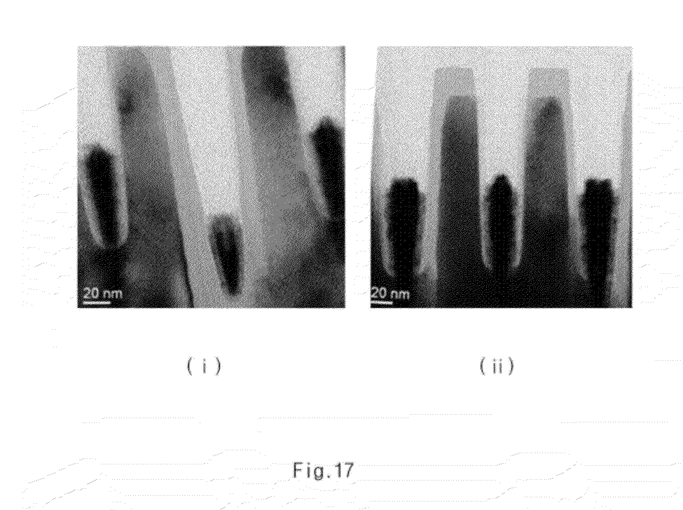

After forming the tungsten nucleation layer, a process for forming the tungsten bulk layer by the reaction of WF₆ and H₂ may be maintained at a temperature of less than 350° C. In more detail, the tungsten bulk layer may be formed at a temperature of 290° C. to 340° C. If the temperature is 350° C. or higher, the growth speed of the tungsten bulk layer is increased so that the crystal size of the tungsten bulk layer is further increased. A detailed description thereof will be described with reference to FIG. 17.

FIG. 17(i) shows an image captured by a transmission electron microscope (TEM) showing a tungsten bulk layer formed by reaction of WF₆ and H₂ at a temperature of 350° C. or higher, and FIG. 17(ii) shows a TEM image of a tungsten bulk layer formed by reaction of WF₆ and H₂ at a temperature of less than 350° C. Referring to FIG. 17(i), when forming the tungsten bulk layer by reacting WF₆ and H₂ at a temperature of 350° C. or higher, the tungsten bulk layer crystal is increased in size, and an upper part of the trench of the buried gate is clogged with the tungsten bulk layer crystal, so that a seam occurs in the tungsten bulk layer and the damage or loss of the tungsten bulk layer is increased due to the execution of a subsequent etchback process, resulting in increased resistance of a gate line. However, as shown in FIG. 17(ii), when forming the tungsten bulk layer by reacting WF₆ and H₂ at a temperature of less than 350° C., the damage or loss of the tungsten bulk layer hardly occurs although the etchback process is performed.

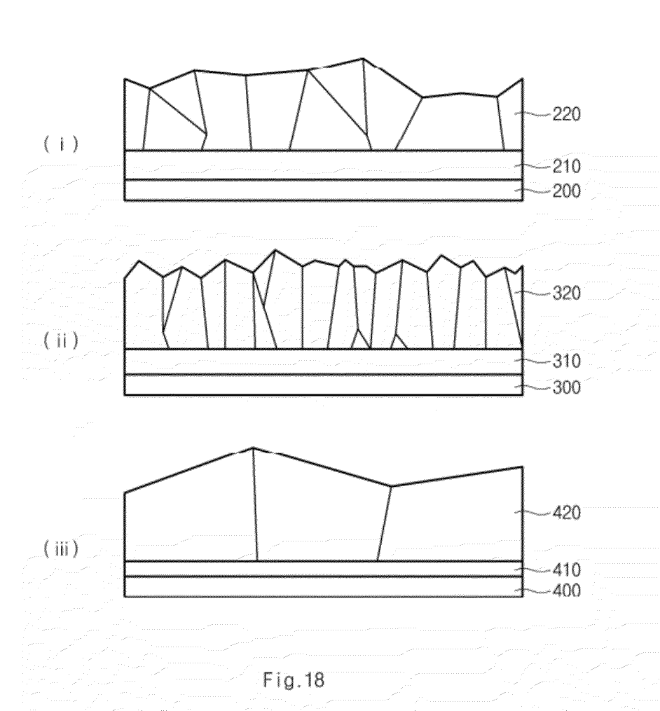

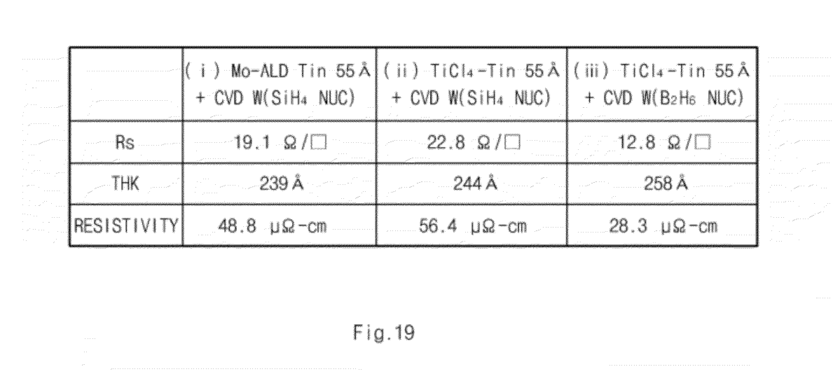

FIG. 18(i) is a cross-sectional view illustrating an MOALD-based TiN layer and a SiH₄-based tungsten crystal formed thereon, FIG. 18(ii) is a cross-sectional view illustrating a TiN layer formed according to an embodiment of the present invention and a SiH₄-based tungsten crystal formed thereon, and FIG. 18(iii) is a cross-sectional view illustrating an inventive TiN layer and a B₂H₂-based tungsten crystal formed thereon. FIG. 19 is a table showing a comparison between the characteristics of structures shown in FIG. 18(i), FIG. 18(ii) and FIG. 18(iii).

Referring to FIG. 18(i), the SiH₄-based tungsten nucleation layer 210 is formed over the MOALD-based TiN layer 200. In this implementation, the tungsten bulk layer 220 is formed over a TiN layer 200 close to an amorphous phase, the crystal size is increased. However, the MOALD-based TiN layer 200 has high resistivity so that it is difficult for the MOALD-based TiN layer 200 to be used as a barrier metal layer. As shown in FIGS. 18(ii) and 18(iii), the TiN (300 or 400) formed by a method according to an embodiment of the present invention may be used as a barrier metal layer.

However, as shown in FIG. 18(ii), the SiH₄-based tungsten nucleation layer 310 has the structure of α-tungsten (α-W) and β-tungsten (β-W), so that the tungsten bulk layer 320 formed over the SiH₄-based tungsten nucleation layer 310 is smaller in crystal size than the tungsten bulk layer 220 of FIG. 18(i), resulting in increased resistance between resistivity and gate line resistance.

Referring to FIG. 18(iii), the B₂H₆-based tungsten nucleation layer 410 has a β-tungsten (β-W) structure close to an amorphous phase, so that the grain size of the tungsten bulk layer 420 formed on the B₂H₆-based tungsten nucleation layer 410 is larger than that of the tungsten bulk layer 220 shown in FIG. 18(i). In addition, the tungsten nucleation layer 410 has a small thickness so that resistivity and gate line resistance are reduced.

Therefore, as shown in FIG. 19(iii), the method for forming the semiconductor device according to an embodiment of the present invention includes forming a TiN layer having a thickness of 100 Å or less using TiCl₄ gas, and the B₂H₆-based tungsten nucleation layer has lower resistivity and lower gate line resistance than structures of FIGS. 19(i) and 19(ii).

As is apparent from the above description, when forming a buried gate, a TiN layer is formed using TiCl₄ gas so that resistivity of the barrier metal layer can be reduced and a stable-phase TiN layer can be obtained using TiCl₄ gas. In addition, TiCl₄ gas is used so that throughput is increased and productivity is improved. When a gate metal layer is formed using the B₂H₆ based nucleation layer, physical properties of the nucleation material have a β-tungsten (β-W) structure regardless of a crystal phase of the barrier metal layer, so that the grain of the gate metal layer is increased in size and resistivity can be reduced. Although the relative amount of the barrier metal layer is increased as compared to the gate metal layer because a critical dimension (CD) is reduced due to the increasing integration degree of the semiconductor device, an embodiment of the present invention can prevent resistance of the gate electrode from being increased. The B₂H₆-based tungsten nucleation layer can be grown to have a small thickness, and the volume of the gate metal layer is increased so that resistivity can be reduced. In addition, the B₂H₆-based tungsten nucleation layer has a β-tungsten (β-W) structure so that it can be used as a diffusion barrier.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A semiconductor device comprising:
a trench provided in a semiconductor substrate;
a barrier metal layer formed over a surface of the trench, and having a thickness of 100 Å or less;
a nucleation layer formed over the barrier metal layer and within the trench, and having a β-tungsten (β-W) structure; and
a bulk layer formed over the nucleation layer and within the trench.

2. The semiconductor device according to claim 1, wherein the barrier metal layer includes a titanium nitride (TiN) layer.

3. The semiconductor device according to claim 1, wherein the bulk layer includes tungsten (W).

4. The semiconductor device according to claim 1, wherein a laminated structure of the barrier metal layer, the nucleation layer, and the bulk layer forms a buried gate.

5. The semiconductor device according to claim 1, further comprising:
a gate oxide film formed under the barrier metal layer and formed over the surface of the trench.

6. A method for forming a semiconductor device comprising:
forming a trench by etching a semiconductor substrate;
forming a barrier metal layer having a thickness of 100 Å or less over a surface of the trench;
forming a nucleation layer over the barrier metal layer and within the trench, the nucleation layer being configured to include a β-tungsten (β-W) structure; and
forming a bulk layer over the nucleation layer within the trench.

7. The method according to claim 6, further comprising:
forming a gate oxide film over the surface of the trench after forming the trench.

8. The method according to claim 6, wherein the forming of the barrier metal layer is performed according to a sequential flow deposition (SFD) scheme.

9. The method according to claim 8, wherein the forming of the barrier metal layer is performed at a temperature of 650° C. or higher.

10. The method according to claim 8, wherein the forming of the barrier metal layer includes:
forming a titanium nitride (TiN) layer by reacting TiCl₄ gas and NH₃ gas;
performing a first purge process;
performing a NH₃ treatment process;
performing a second purge process; and
repeating the forming a titanium nitride, first purge process, NH₃ treatment process, and the second purge process until the TiN layer is formed to a have a specific thickness.

11. The method according to claim 10, wherein a ratio of TiCl₄ gas to NH₃ gas is maintained at 1:1.

12. The method according to claim 10, wherein the TiN layer is deposited to a thickness of 5 Å or less.

13. The method according to claim 10, wherein the first purge process is performed for a time that is equal to or greater than a time for the forming of the TiN layer.

14. The method according to claim 10, wherein the first purge process pumps out by-products generated in the formation of the TiN layer and non-reacted gas.

15. The method according to claim 10, wherein the NH₃ treatment process is performed for a time that is equal to or greater than a time for the forming of the TiN layer.

16. The method according to claim 10, wherein the NH₃ treatment process increases purity of the TiN layer by reaction with a chlorine (Cl).

17. The method according to claim 6, wherein the forming of the nucleation layer is performed at a temperature of 290° C. to 310° C.

18. The method according to claim 6, wherein the forming of the nucleation layer includes:
injecting and flowing B₂H₆ gas;
after injecting and flowing the B₂H₆ gas, performing a third purge process;
injecting and flowing WF₆ gas;
performing a fourth purge process; and
repeating the injecting and flowing B₂H₆ gas, the third purge process, the injecting and flowing WF₆ gas, and the fourth purge process, until the nucleation layer is formed to a have a specific thickness.

19. The method according to claim 18, wherein the third purge process is performed for a predetermined time that is at least two times longer than a time for injecting/flowing the B₂H₆ gas.

20. The method according to claim 18, wherein the fourth purge process is performed for a predetermined time that is at least ten times longer than a time for injecting/flowing the WF₆ gas.

21. The method according to claim 6, wherein the forming of the nucleation layer includes:
injecting and flowing B₂H₆ gas;
performing a fifth purge process;
injecting and flowing WF₆ gas;
performing a sixth purge process;
injecting and flowing SiH₄ gas;
performing a seventh purge process;
injecting and flowing WF₆ gas;
performing an eighth purge process; and
repeating the injecting and flowing B₂H₆ gas, the fifth purge process, the injecting and flowing WF₆ gas, the sixth purge process, the injecting and flowing SiH₄ gas, and the eighth purge process until the nucleation layer has a specific thickness, and performing B₂H₆ treatment.

22. The method according to claim 21, wherein the performing B₂H₆ treatment includes:
injecting and flowing B₂H₆ gas; and
performing a ninth purge process several times.

23. The method according to claim 6, wherein the forming of the bulk layer includes reacting WF₆ gas and H₂ gas.

24. The method according to claim 6, wherein the forming of the bulk layer is performed at a temperature of less than 350° C.
